(19) United States
(12) Patent Application Publication
(10) Pub. No.: US 2023/0134850 A1
(43) Pub. Date: May 4, 2023

(54) SEMICONDUCTOR POWER DEVICE WITH SHORT CIRCUIT PROTECTION AND PROCESS FOR MANUFACTURING A SEMICONDUCTOR POWER DEVICE

(71) Applicant: STMICROELECTRONICS S.R.L., Agrate Brianza (IT)

(72) Inventors: Salvatore CASCINO, Gravina di Catania (IT); Alfio GUARNERA, Trecastagni (IT); Mario Giuseppe SAGGIO, Aci Bonaccorsi (IT)

(73) Assignee: STMICROELECTRONICS S.R.L., Agrate Brianza (IT)

(21) Appl. No.: 18/045,784

(22) Filed: Oct. 11, 2022

(30) Foreign Application Priority Data
Oct. 29, 2021 (IT) 102021000027842

(51) Int. Cl. H01L 29/06; H01L 29/78; H01L 29/66; H01L 21/04

(52) U.S. Cl. CPC H01L 29/0607; H01L 29/7802; H01L 29/66068; H01L 21/0465; H01L 29/1608

(57) ABSTRACT

A semiconductor power device has a maximum nominal voltage and includes: a first conduction terminal and a second conduction terminal; a semiconductor body, containing silicon carbide and having a first conductivity type; body wells having a second conductivity type, housed in the semiconductor body and separated from one another by a body distance; source regions housed in the body wells; and floating pockets having the second conductivity type, formed in the semiconductor body at a distance from the body wells between a first face and a second face of the semiconductor body. The floating pockets are shaped and arranged relative to the body wells so that a maximum intensity of electrical field around the floating pockets is greater than a maximum intensity of electrical field around the body wells at least for values of a conduction voltage between the first conduction terminal and the second conduction terminal greater than a threshold voltage, the threshold voltage being less than the maximum nominal voltage.

### BACKGROUND

### Technical Field

The present disclosure relates to a semiconductor power device with short circuit protection and to a process for manufacturing a semiconductor power device.

### Description of the Related Art

It is known that, in semiconductor power devices, the tendency to reduce the dimensions to obtain high performance can expose to various conditions of risk that mainly involve certain parameters. A significant problem not only for conventional silicon power devices, but also for those based upon special materials like silicon carbide, is that of short circuit strength, often defined through the short-circuit withstand time. The current density within devices can reach extremely high values, in particular around structures like the junctions between the body wells and the drift region. Excessively high current densities may be the cause of intense local heating and even irreversible damage. For instance, heating may trigger phenomena of uncontrolled generation of electron-hole pairs (“thermal runaway”), which result in conditions of short circuit between drain regions and source regions and may not be stopped even by switching off the device. The short-circuit withstand time indicates how much a device is able to function in given conditions of current before a thermal short circuit occurs. The longer the short-circuit withstand time, the longer a device is able to function without suffering damage.

Given that the problem is mainly linked to the current density and to the local dissipation of power, it is clear that the reduction of the dimensions (shrinkage) of the devices may have negative effects, unless the performance requirements are reduced. The reduction in dimensions encounters limits due to triggering of short circuits even in devices of silicon carbide, even though this has a thermal conductivity much higher than that of other semiconductor materials and is therefore able to dissipate the heat more efficiently.

Various circuit solutions have been proposed to prevent or circumscribe potentially dangerous conditions. However, regardless of the effectiveness, they all lead to a significant increase in terms of cost and area occupied.

The structural solutions aimed simply at reducing the ON-state drain-to-source resistance (normally denoted by R_{DSON}) lead to limited benefits that, in any case, are not sufficient to increase in a satisfactory way the short-circuit withstand time.

Consequently, as a whole the tendency to reduce the dimensions of power devices to obtain higher levels of performance is hindered by the problems due to the excessively high current density.

### BRIEF SUMMARY

The present disclosure is directed to providing a semiconductor power device and a process for manufacturing a semiconductor power device that will enable the limitations described to be overcome or at least mitigated.

The present disclosure is directed to a semiconductor power device that includes a first conduction terminal and a second conduction terminal. The device includes a semiconductor body containing silicon carbide and having a first conductivity type. Body wells having a second conductivity type, are in the semiconductor body and separated from one another by a body distance. Source regions are in the body wells. An enrichment layer is at a surface of the semiconductor body. Floating pockets having the second conductivity type, in the semiconductor body are at a distance from the body wells between a first face and a second face of the semiconductor body, the enrichment layer is between the first face and the body wells.

### BRIEF DESCRIPTION OF THE SEVERAL VIEWS OF THE DRAWINGS

For a better understanding of the disclosure, some embodiments thereof will now be described, purely by way of non-limiting example and with reference to the attached drawings, wherein:

FIG. 1A is a cross-sectional view through a semiconductor power device according to an embodiment of the present disclosure;

FIG. 1B is an equivalent electrical symbol of the power device of FIG. 1A;

FIGS. 2 and 3 are graphs relative to a distribution of intensity of electrical field in a known power device and in the power device of FIG. 1, respectively;

FIG. 4 is a graph that shows short-circuit withstand times in a known power device and in the power device of FIG. 1;

FIGS. 5 and 6 are graphs relative to a distribution of potential in a known power device and in the power device of FIG. 1, respectively;

FIG. 7 is a cross-sectional view through a semiconductor power device according to a different embodiment of the present disclosure;

FIG. 8 is a cross-sectional view through a semiconductor power device according to a further embodiment of the present disclosure; and

FIGS. 9-13 are cross-sectional views of a semiconductor wafer during successive steps of a process for manufacturing a semiconductor power device according to an embodiment of the present disclosure.

### DETAILED DESCRIPTION

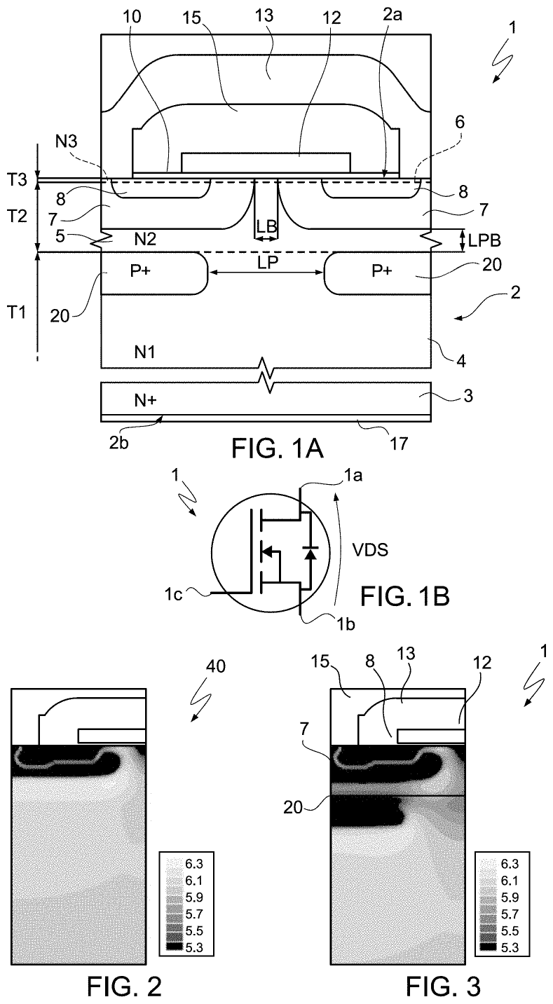

With reference to FIGS. 1A and 1B, a semiconductor power device according to an embodiment of the present disclosure is designated, as a whole, by the number 1, has a drain terminal 1a, a source terminal 1b and a gate terminal 1c and comprises a semiconductor body 2 of silicon carbide. The semiconductor body 2, in turn, comprises a substrate 3, a first epitaxial layer 4, formed on the substrate 3 and having a first thickness T1, and a second epitaxial layer 5, formed on the first epitaxial layer 4 and having a second thickness T2 smaller than the first thickness T1. For instance, the first thickness T1 is comprised in the range 10-30 μm, and the second thickness T2 is comprised in the range 0.8-2 μm. The first epitaxial layer 4 and the second epitaxial layer 5 both have a first conductivity type, for example of an N type. The first epitaxial layer 4 has, however, a first doping level N1 lower than a second doping level N2 of the second epitaxial layer. For instance, the first doping level N1 is in the order of 10¹⁶ atoms/cm³, whereas the second doping level N2 is in the order of 10¹⁷ atoms/cm³. In an embodiment, the semiconductor body 2 also comprises an enrichment layer 6, having a third thickness T3 smaller than the first thickness T1 and the second thickness T2 (for example 0.1 μm), the first conductivity type (N), and a third native doping level N3 higher than the first doping level N1 and the second doping level N2. The enrichment layer 6 may be a further epitaxial layer or may be obtained by implantation. The substrate 3 is of an N+ type and has a doping level, for example, in the order of 10¹⁸ atoms/cm³.

Body wells 7, having a second conductivity type, here of a P type, are formed within the second epitaxial layer 5 and house respective source regions 8, with the first conductivity type, in particular of an N+ type. The second epitaxial layer 5 defines a current spread layer (CSL), which extends to a greater depth from a first face 2a of the semiconductor body 2 as compared to the body wells 7, and the body wells 7 are embedded in the current spread layer. In other words, the second thickness T2 of the second epitaxial layer 5, which corresponds to the depth of the current spread layer, is greater than the depth of the body wells 7 from the first face 2a.

The body wells 7 are separated from one another by a body distance LB of less than 1 μm, for example 0.6 μm. The body wells 7 and the portion of the second epitaxial layer 5 comprised between them forms a parasitic-JFET region. A gate dielectric layer 10 extends on the first face 2a of the semiconductor body 2 over the second epitaxial layer 5 (or over the enrichment layer 6, if present) between the source regions 8 and is surmounted by a gate region 12. A source contact 13 extends over the source regions 8 and the gate region 12. An intermetal dielectric layer 15 insulates the gate region 12 from the source contact 13. A drain contact 17 is formed on a second face 2b of the semiconductor body 2 opposite to the first face 2a.

At an interface with the overlying epitaxial layer, i.e., the second epitaxial layer 5, the first epitaxial layer 4 houses floating protection pockets 20 having the second conductivity type, for example of a P+ type, with a doping level in the order of 10¹⁸ atoms/cm³. Furthermore, the floating pockets 20 are shaped and arranged relative to the structures in the semiconductor body 2 so that the maximum intensity of the electrical field around the floating pockets 20 is greater than the maximum intensity of the electrical field around the body wells 7 at least for values of drain-to-source voltage VDS higher than a threshold voltage. The threshold voltage is less than a maximum nominal voltage, for example equal to 25%, or to 50% or to 65% of the maximum nominal voltage. The floating pockets 20 are arranged underneath corresponding body wells 7 and are separated from one another by a protection distance LP greater than the body distance LB, for example, a difference between the protection distance LP and the body distance LB is comprised between 0.5 μm and 1.5 μm. A protection-to-body distance LPB between the floating pockets 20 and the corresponding body wells 7 in a direction perpendicular to the faces 2a and 2b of the semiconductor body 2 is less than 0.5 μm. In practice, the depth of the body wells 7 from the first face 2a of the semiconductor body 2 is at the most 0.5 μm less than the second thickness T2 of the second epitaxial layer 5.

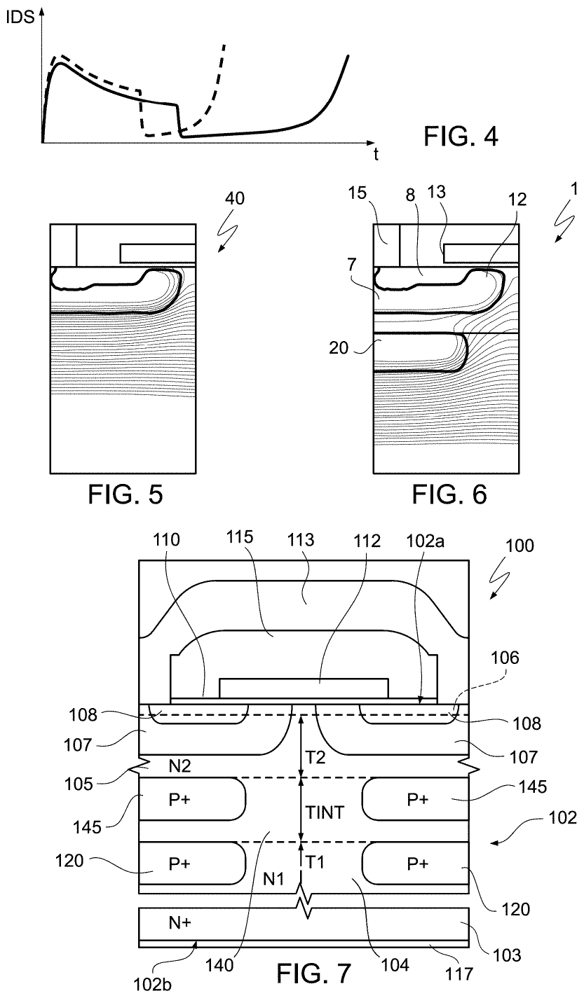

The power device 1 may be configured to operate with a gate-to-source voltage of 18 V, a maximum nominal voltage (maximum drain-to-source voltage VDS) beyond 1 kV, for example 1.2 kV or 3.3 kV, and currents of even several hundreds of amps or even higher. The floating pockets 20, as defined above, enable reduction of the intensity of the electrical field around the most critical regions, i.e., the junctions between the body wells 7 and the second epitaxial layer 5, where the combination with the particularly high current density is unfavorable, also due to the dimensions of the parasitic-JFET region. The situation of the electrical field is represented in FIGS. 2 and 3 directly and, furthermore, in FIGS. 5 and 6 through potential lines, respectively for a conventional power device 40 (FIGS. 2 and 5) and for the power device 1 of FIG. 1A (FIGS. 3 and 6). As may be noted, in the conventional power device, the potential lines are particularly crowded around the body well and the values of electrical field are accordingly high. In the power device 1, instead, above the threshold voltage and in conditions of conduction the potential lines are less crowded in the entire parasitic-JFET region and become more crowded around the floating pockets 20. In practice, then, the higher values of electrical field become deeper in the first epitaxial layer 4, where, however, the current density is markedly reduced because the region between the floating pockets 20 is much wider than the parasitic-JFET region. In this way, the time necessary for triggering the phenomena that lead in an uncontrolled way to short circuit due to excessive local heating, i.e., the short-circuit withstand time, is advantageously increased, as illustrated in the graph of FIG. 4. Here, the dashed line refers to a conventional power device, whereas the solid line refers to the power device 1 according to the disclosure.

The effect of reduction of the electrical field in the critical regions around the body wells 7 and the corresponding increase of the short-circuit withstand time is also favored by the protection-to-body distance LPB between the floating pockets 20 and the body wells 7. The protection-to-body distance LPB is in fact selected so that, at least for values of drain-to-source voltage VDS higher than the threshold voltage, the potential lines tend not to wrap around the body wells 7 and instead tend to stretch out towards the floating pockets 20, without penetrating or penetrating only marginally into the portion of the second epitaxial layer 5 comprised between the floating pockets 20 and the body wells 7. A greater distance would not allow stretching out of the potential lines and the corresponding reduction of the electrical field in the critical zones, in particular in the parasitic-JFET region.

A further advantage is represented by the fact that the improvement of the short-circuit withstand time is made possible without altering significantly either the breakdown voltage or the ON-state drain-to-source resistance, normally denoted as R_{DSON}. Rather, also an increase in the thickness of the current spread layer defined by the second epitaxial layer 5 in the order of 10-20% does not affect the breakdown voltage, which instead decreases in conventional power devices.

With reference to FIG. 7, in an embodiment a semiconductor power device 100 comprises a semiconductor body 102 of silicon carbide that includes, substantially as already described, a first epitaxial layer 104 and a second epitaxial layer 105, where body wells 107 and source regions 108 are formed. An enrichment layer 106 may be present on the surface of the semiconductor body 102. As in the embodiment of FIG. 1A, formed on a first face 102a of the semiconductor body 102 are a gate dielectric layer 110, a gate region 112, a source contact 113 and an intermetal dielectric layer 115. A drain contact 117 is formed on a second face 102b of the semiconductor body 102 opposite to the first face 102a.

The semiconductor body 102 furthermore comprises an intermediate epitaxial layer 140, arranged between the first epitaxial layer 104 and the second epitaxial layer 105 and having a thickness TINT substantially equal to the thickness T2 of the second epitaxial layer 105 (for example, comprised in the range 0.8-2 μm).

The doping levels diminish from the second epitaxial layer 105 (the highest, if an enrichment layer is not present, for example 10¹⁷ atoms/cm³), to the intermediate epitaxial layer 140 (which is intermediate also in doping, in addition to its position, for example 4×10¹⁶ atoms/cm³) and to the first epitaxial layer 104 (the lowest, for example 10¹⁶ atoms/cm³). In the case where the enrichment layer 106 is present, its doping level is the highest, for example 3×10¹⁷ atoms/cm³.

At an interface with the overlying epitaxial layer, in this case the intermediate epitaxial layer 140, the first epitaxial layer 104 houses deep floating protection pockets 120 having the second conductivity type, for example of a P+ type with a doping level in the order of 10¹⁸ atoms/cm³.

At an interface with the second epitaxial layer 105, the intermediate epitaxial layer 140 houses intermediate floating pockets 145 that are substantially the same as the deep floating pockets 120.

The deep floating pockets 120 and the intermediate floating pockets 145 are shaped and arranged relative to the structures in the semiconductor body 102 so that the maximum intensity of the electrical field around the deep floating pockets 120 is greater than the maximum intensity of the electrical field around the body wells 107 at least for values of drain-to-source voltage VDS higher than a threshold voltage, which is less than a maximum nominal voltage. In particular, distances in a direction perpendicular to the faces 102a, 102b of the semiconductor body 102 between the deep floating pockets 120 and the intermediate floating pockets 145 and between the intermediate floating pockets 145 and the body wells 107 are less than 0.5 μm, for example 0.3 μm. These distances are not necessarily the same as one another.

The presence of protection wells on a number of levels enables amplification of the effect of translation of the high values of electrical field towards the inside of the semiconductor body 102, at a greater distance from the first face 102a.

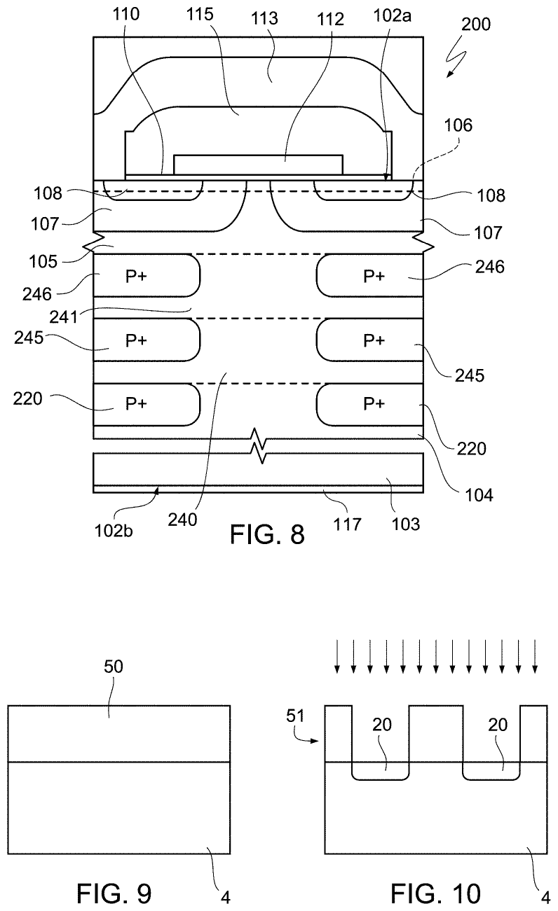

The number of levels of protection wells is not limited to two. In other embodiments, as in the semiconductor power device 200 of FIG. 8, in addition to the deep protection wells here designated by 220, there may be present, for example, two intermediate levels of protection wells 245, 246, or even a higher number, according to the design preferences. The intermediate floating pockets of each level are formed in respective intermediate epitaxial layers 240, 241.

The power device 1 of FIG. 1A may be manufactured with the process described in the following with reference to FIGS. 9-13. Initially, the first epitaxial layer 4 is formed for the desired thickness. Then, a first mask layer 50 of TEOS (TetraEthylOrthoSilicate) is deposited and planarized.

The first mask layer 50 is then patterned (FIG. 10) to form a first implantation mask 51, which is then used for producing the floating pockets 20 by a first implantation P as far as the desired depth. The first implantation P in an embodiment is a multiple implantation in a number of steps, which enables a precise control of the implantation depth and of the shape of the floating pockets 20. The implanted dopant species may be aluminum, and the implantation may be performed in five steps, as defined in the table below.

| | Concentration | Implantation |
|---|---|---|
| Dopant species | [atoms/cm³] | energy [keV] |
| Al+ | 10¹² | 30 |
| Al+ | 10¹² | 80 |
| Al+ | 10¹³ | 160 |
| Al++ | 3.12 × 10¹³ | 300 |
| Al++ | 5.20 × 10¹³ | 400 |

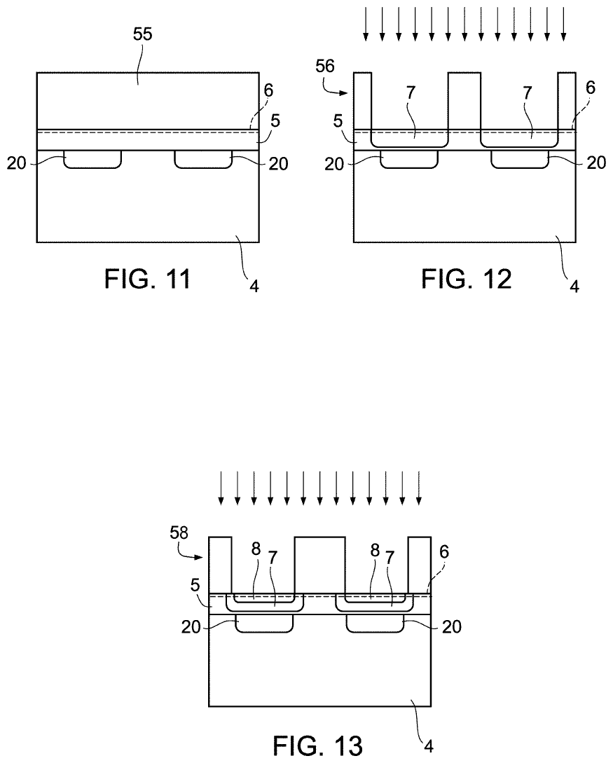

After removal of the first implantation mask 1, the second epitaxial layer 5 is grown, once again for the desired thickness (FIG. 11). If necessary, the enrichment layer 6 is formed through a further epitaxial growth or by surface implantation of dopant species.

A second mask layer 55 is deposited and planarized, and then patterned to form a second implantation mask 56 (FIG. 12), which is used to produce the body wells 7 by a second implantation P as far as the desired depth. Also the second implantation may be a multiple implantation.

The second implantation mask 56 is removed, and a third implantation mask 58 is formed (FIG. 13) from a mask layer (not illustrated entirely) with which the source regions 8 are formed.

The third implantation mask 58 is removed, and the power device 1 is completed with the gate dielectric layer 10, the gate region 12, the intermetal dielectric layer 15, and the source contact 13, and finally by producing the drain terminal 1a, the source terminal 1b, and the gate terminal 1c (FIG. 1B).

Finally, it is clear that modifications and variations may be made to the device and to the process described herein, without thereby departing from the scope of the present disclosure, as defined in the annexed claims.

A semiconductor power device having a maximum nominal voltage and may be summarized as including a first conduction terminal (1a) and a second conduction terminal (1b); a semiconductor body (2; 102) containing silicon carbide and having a first conductivity type; body wells (7; 107) having a second conductivity type, housed in the semiconductor body and separated from one another by a body distance (LB); source regions housed in the body wells (7); and floating pockets (20; 120) having the second conductivity type, formed in the semiconductor body (2; 102) at a distance from the body wells (7; 107) between a first face (2a; 102a) and a second face (2b; 102b) of the semiconductor body (2; 102); wherein the floating pockets (20; 120) are shaped and arranged relative to the body wells (7; 107) so that a maximum intensity of electrical field around the floating pockets (20; 120) is greater than a maximum intensity of electrical field around the body wells (7; 107) at least for values of a conduction voltage (VDS) between the first conduction terminal (1a) and the second conduction terminal (1b) higher than a threshold voltage, the threshold voltage being less than the maximum nominal voltage.

The semiconductor body (2; 102) may include a first epitaxial layer (4; 104), having the first conductivity type and a first doping level (N1), and a second epitaxial layer (5; 105), having the first conductivity type and a second doping level (N2), higher than the first doping level (N1); the body wells (7; 107) are housed in the second epitaxial layer (5; 105); and the floating pockets (20; 120) are housed in the first epitaxial layer (4; 104).

The floating pockets (20; 120) may be housed at an interface of the first epitaxial layer (4; 104) with an epitaxial layer overlying the first epitaxial layer (4; 104).

The epitaxial layer overlying the first epitaxial layer (4) may be the second epitaxial layer (5).

A protection-to-body distance (LPB) between the floating pockets (20) and the corresponding body wells (7) in a direction perpendicular to the first face (2a) and to the second face (2b) of the semiconductor body (2) may be less than 0.5 μm.

The semiconductor body (102) may include an intermediate epitaxial layer (140), arranged between the first epitaxial layer (104) and the second epitaxial layer (105) and having a doping level intermediate between the first doping level (N1) and the second doping level (N2), and the epitaxial layer overlying the first epitaxial layer (104) is the intermediate epitaxial layer (140).

The device may include intermediate floating pockets (145) having the second conductivity type, formed in the intermediate epitaxial layer (140) at an interface with the second epitaxial layer (105).

Distances in a direction perpendicular to the first face (102a) and to the second face (102b) of the semiconductor body (102) between the floating pockets (120) and the intermediate floating pockets (145) and between the intermediate floating pockets (145) and the body wells (107) may be less than 0.5 μm.

The semiconductor body (2; 102) may include a surface enrichment layer (6; 106), having a third native doping level (N3) higher than the first doping level (N1) and the second doping level (N2) and the first epitaxial layer (104) may have a first thickness (T1), the second epitaxial layer (105) may have a second thickness (T2), and the enrichment layer (6; 106) may have a third thickness (T3) smaller than the first thickness (T1) and the second thickness (T2).

The body wells (7; 107) may be separated from one another by a body distance (LB) and the floating pockets (20; 120) may be arranged underneath corresponding body wells (7; 107) and may be separated from one another by a protection distance (LP) greater than the body distance (LB), for example by an amount between 0.5 μm and 1.5 μm.

The body distance (LB) may be less than 1 μm, for example 0.6 μm.

The second epitaxial layer (5; 105) may define a current spread layer, which extends up to a greater depth from the first face (2a; 102a) of the semiconductor body (2; 102) than the body wells (7; 107).

The floating pockets (20; 120) may have the second conductivity type and a doping level in the order of 10¹⁸ atoms/cm³.

A process for manufacturing a semiconductor power device may be summarized as including forming a semiconductor body (2; 102) containing silicon carbide and having a first conductivity type (N); forming body wells (7; 107) having a second conductivity type (P), housed in the semiconductor body and separated from one another by a body distance (LB); forming source regions (8) having the first conductivity type (N) and housed in the body wells (7); and forming floating pockets (20; 120) having the second conductivity type in the semiconductor body (2; 102) at a distance from the body wells (7; 107) between a first face (2a; 102a) and a second face (2b; 102b) of the semiconductor body (2; 102); forming a first conduction terminal (1a) and a second conduction terminal (1b); wherein the floating pockets (20; 120) are shaped and arranged relative to the body wells (7; 107) so that a maximum intensity of electrical field around the floating pockets (20; 120) is greater than a maximum intensity of electrical field around the body wells (7; 107) at least for values of a conduction voltage (VDS) between the first conduction terminal (1a) and the second conduction terminal (1b) greater than a threshold voltage, the threshold voltage being less than the maximum nominal voltage.

Forming the semiconductor body (2; 102) may include forming a first epitaxial layer (4; 104), having the first conductivity type and a first doping level (N1), and a second epitaxial layer (5; 105), having the first conductivity type and a second doping level (N2) higher than the first doping level (N1); and the floating pockets (20; 120) may be formed in the first epitaxial layer (4; 104) and the body wells (7; 107) may be formed in the second epitaxial layer (5; 105).

Forming floating pockets (20) may include forming a first implantation mask (51) on the first epitaxial layer (4) and carrying out a first implantation, for example a first multiple implantation, of a dopant species of the second type using the first implantation mask (51); and forming body wells (7) may include forming a second implantation mask (56) and carrying out a second implantation, for example a second multiple implantation, of a dopant species of the second type using the second implantation mask (56).

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A semiconductor power device, comprising:
a first conduction terminal and a second conduction terminal;
a semiconductor body containing silicon carbide and having a first conductivity type;
body wells having a second conductivity type, in the semiconductor body and separated from one another by a body distance;
source regions in the body wells;
an enrichment layer; and
floating pockets having the second conductivity type, in the semiconductor body at a distance from the body wells between a first face and a second face of the semiconductor body, the enrichment layer being between the first face and the body wells.

2. The device according to claim 1 wherein:
the semiconductor body includes a first epitaxial layer, having the first conductivity type and a first doping level, and a second epitaxial layer, having the first conductivity type and a second doping level, higher than the first doping level;
the body wells are in the second epitaxial layer; and
the floating pockets are in the first epitaxial layer.

3. The device according to claim 2 wherein the floating pockets are at an interface of the first epitaxial layer with the second epitaxial layer.

4. The device according to claim 1 wherein the floating pockets are spaced from each other by a protection distance that is greater than the body distance.

5. The device according to claim 4 wherein a protection-to-body distance between the floating pockets and the corresponding body wells in a direction perpendicular to the first face and to the second face of the semiconductor body is less than 0.5 μm.

6. The device according to claim 4 wherein a protection-to-body distance between the floating pockets and the corresponding body wells in a direction transverse to the first face and to the second face of the semiconductor body is less than the body distance.

7. The device according to claim 3 wherein the semiconductor body comprises an intermediate epitaxial layer, arranged between the first epitaxial layer and the second epitaxial layer and having a doping level intermediate between the first doping level and the second doping level, and wherein the epitaxial layer overlying the first epitaxial layer is the intermediate epitaxial layer.

8. The device according to claim 7, comprising intermediate floating pockets having the second conductivity type, in the intermediate epitaxial layer at an interface with the second epitaxial layer.

9. The device according to claim 2 wherein the enrichment layer has a third native doping level higher than the first doping level and the second doping level and wherein the first epitaxial layer has a first thickness, the second epitaxial layer has a second thickness, and the enrichment layer has a third thickness smaller than the first thickness and the second thickness.

10. The device according to claim 1 wherein the floating pockets are arranged underneath corresponding body wells and are separated from one another by a protection distance greater than the body distance, the body distance being in the range of 0.5 μm and 1.5 μm.

11. The device according to any claim 1 wherein the body distance is less than 1 μm.

12. A method, comprising:
forming body wells in a semiconductor body containing silicon carbide and having a first conductivity type, the body wells having a second conductivity type and are separated from one another by a body distance;
forming source regions having the first conductivity type in the body wells; and
forming floating pockets having the second conductivity type in the semiconductor body at a distance from the body wells between a first face and a second face of the semiconductor body;
forming the floating pockets spaced apart from each other by a protection distance that is less than the body distance.

13. The method according to claim 12, comprising forming a first epitaxial layer, having the first conductivity type and a first doping level, and a second epitaxial layer, having the first conductivity type and a second doping level higher than the first doping level; and forming the floating pockets in the first epitaxial layer and forming the body wells in the second epitaxial layer.

14. The method according to claim 13 wherein forming floating pockets comprises forming a first implantation mask on the first epitaxial layer and carrying out a first implantation of a dopant species of the second type using the first implantation mask; and forming body wells comprises forming a second implantation mask and carrying out a second implantation of a dopant species of the second type using the second implantation mask.

15. A device, comprising:
a substrate having a first conductivity type;
a first and second floating pocket in the substrate and having a second conductivity type;
a first layer on the substrate, the first layer having the first conductivity type;
a first and second body well in the first layer, the first and second body well having the second conductivity type, the first and second body well being spaced from the first and second floating pockets by a first distance in a first direction, the first body well being spaced from the second body well by a second distance in a second direction that is transverse to the first direction, the first floating pocket being spaced from the second floating pocket by a third distance in the second direction, the third distance being greater than the second distance.

16. The device of claim 15, comprising an enrichment layer at a surface of the first layer, the enrichment layer having the first conductivity type.

17. The device of claim 16, comprising a gate dielectric on the surface of the first layer and a gate on the gate dielectric.

18. The device of claim 17, comprising a source contact on the gate and a drain contact on the substrate, the drain contact spaced from the first and second body well by the first and second floating pocket.
